(19) United States
(12) Patent Application Publication
(10) Pub. No.: US 2026/0118624 A1
(43) Pub. Date: Apr. 30, 2026

(54) DISPLAY PANEL HOLDER AND HEAD-MOUNTED DISPLAY

(71) Applicant: SONY INTERACTIVE ENTERTAINMENT INC., Tokyo (JP)

(72) Inventors: Yasutoshi KATSUDA, Kanagawa (JP); Shotaro TADA, Aichi (JP); Satoshi KURATA, Kanagawa (JP)

(73) Assignee: SONY INTERACTIVE ENTERTAINMENT INC., Tokyo (JP)

(21) Appl. No.: 19/431,617

(22) Filed: Dec. 23, 2025

Related U.S. Application Data
(63) Continuation of application No. PCT/JP2023/024519, filed on Jun. 30, 2023.

(51) Int. Cl. G02B 7/02; G02B 25/00; H10K 59/18; H10K 59/80

(52) U.S. Cl. CPC G02B 7/023; G02B 25/001; H10K 59/18; H10K 59/879

(57) ABSTRACT

There is provided a display panel holder (40) for holding a display panel (10) provided in an HMD (1) that is worn on a head of a user (U). The display panel holder (40) includes a panel holding part (41) that internally houses and holds one or more display panels (10) each having a display region for displaying an image. The panel holding part (41) has positional adjustment holes formed therein to receive an operation for a positional adjustment of the display panel (10) from the outside of the panel holding part (41).

### CROSS-REFERENCE TO RELATED APPLICATIONS

This application is a Continuation application under 35 U.S. C. § 111 of International Application No. PCT/JP2023/024519, filed Jun. 30, 2023, the entire disclosure of which is incorporated herein by reference in its entirety for all purposes.

### TECHNICAL FIELD

The present disclosure relates to a display panel holder and a head-mounted display (HMD).

### BACKGROUND OF THE INVENTION

### Background Art

Conventionally, HMDs having display panels for displaying images have been known as described in PTL 1.

### PATENT LITERATURE

PCT Patent Publication No. WO2016/136657

### BRIEF SUMMARY OF THE INVENTION

### Technical Problem

Here, in a case where a display panel is not held in an appropriate position, a user cannot view appropriate video. Specifically, the user will view blurred video or tilted video.

It is one of objects of the present disclosure to provide a display panel holder and an HMD that improve positional accuracy of a display panel.

### Solution to Problem

An HMD proposed in the present disclosure is an HMD that is worn on a head of a user, the HMD including an eyepiece located in front of an eye of the user wearing the HMD, a display panel having at least a first display region for displaying a first image and a second display region for displaying a second image discontinuously with the first image, a first lens part configured to guide first image light emitted from the first display region to the eyepiece and magnify the first image to thereby allow the user to view the magnified first image, and a second lens part configured to guide second image light emitted from the second display region to the eyepiece and magnify the second image to thereby allow the user to view the magnified second image.

### BRIEF DESCRIPTION OF DRAWINGS

FIG. 1A is a perspective view of an HMD according to a present embodiment as viewed from the left front.

FIG. 1B is a left side view of the HMD according to the present embodiment as viewed from the left side.

FIG. 2 is a diagram schematically illustrating configurations of display panels and an optical system in the present embodiment.

FIG. 3 is a plan view of the display panels in the present embodiment as viewed from the front.

FIG. 4A is a diagram illustrating an example of a display image in a case where a lattice pattern is displayed in each display region.

FIG. 4B is a diagram illustrating an example of a display image in a case where a circular object is displayed.

FIG. 5A is a diagram illustrating an example of a display image that a user can view via lens parts in the case where the lattice pattern is displayed in each display region.

FIG. 5B is a diagram illustrating an example of a display image that the user can view via the lens parts in the case where the circular object is displayed.

FIG. 6 is a diagram illustrating display panels in a first modification.

FIG. 7 is a diagram illustrating a display panel in a second modification.

FIG. 8 is a perspective view of a display unit as viewed diagonally from the upper right.

FIG. 9 is a perspective view of the display unit as viewed diagonally from the lower right.

FIG. 10 is a front view of the display unit as viewed from the front.

FIG. 11 is a sectional view illustrating a section of the display unit corresponding to a cutting line XI-XI of FIG. 10.

FIG. 12 is a sectional view illustrating a section of the display unit corresponding to a cutting line XII-XII of FIG. 10.

FIG. 13A is a diagram schematically illustrating an example of a manner of making a positional adjustment of the display panel.

FIG. 13B is a diagram schematically illustrating an example of a manner of making a positional adjustment of the display panel.

FIG. 13C is a diagram schematically illustrating an example of a manner of making a positional adjustment of the display panel.

FIG. 14 is a diagram schematically illustrating an example of a manner of making a positional adjustment of the display panel.

### DETAILED DESCRIPTION OF THE INVENTION

An embodiment of the present invention (hereinafter referred to as a present embodiment) will be described below with reference to the drawings. In the following description, a head-mounted display 1 will be referred to as an “HMD 1.” In addition, in the following description, directions indicated by X1 and X2 in the figures will respectively be set as a right direction and a left direction, directions indicated by Y1 and Y2 in the figures will respectively be set as an upward direction and a downward direction, and directions indicated by Z1 and Z2 in the figures will respectively be set as a forward direction and a rearward direction. Each of these directions represents a direction as viewed from a user wearing the HMD 1. However, the left and right directions, the upward and downward directions, and the forward and rearward directions do not represent precise directions.

### Outline of HMD 1

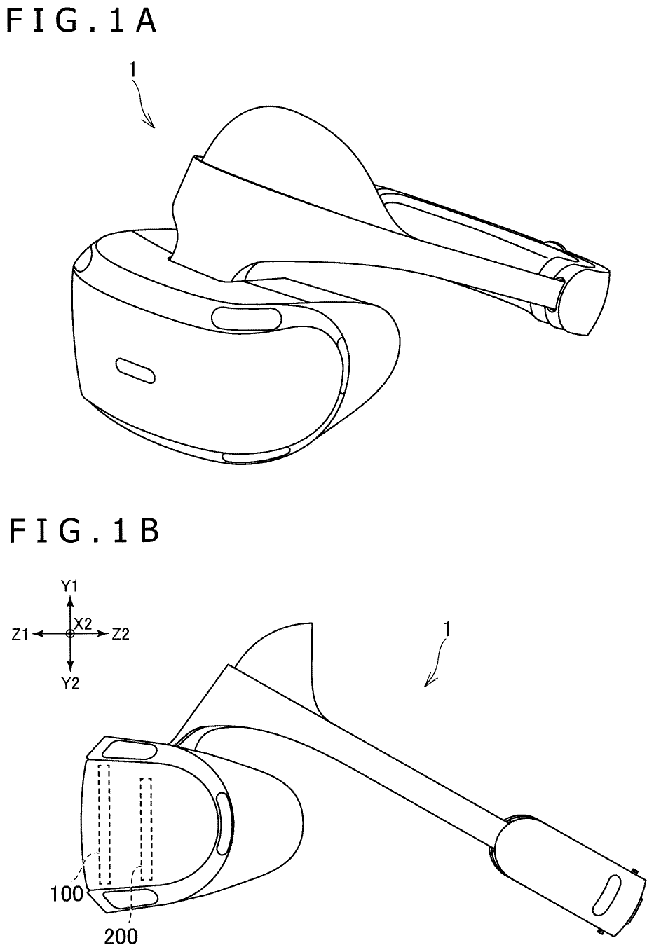

FIG. 1A is a perspective view of the HMD according to the present embodiment as viewed from the left front. FIG. 1B is a left side view of the HMD according to the present embodiment as viewed from the left side. It is to be noted that, in the following description, a state in which the HMD 1 is worn by the user will be referred to as a “usage state.” In the usage state, a region in front of the user's eyes is covered by the HMD 1.

The HMD 1 preferably includes a fitting band to be placed around the user's head and a main body housing supported by a front portion of the fitting band. The main body housing houses various members such as a display unit 100 and an eyepiece 200 constituting an optical system.

The display unit 100 includes display panels 10 to be described later. The display panels 10 preferably display a two-dimensional image or a three-dimensional image. Each of the display panel 10 is preferably a liquid crystal display or an organic electroluminescence display device, for example. However, the kind of the display panel 10 is not particularly limited.

The HMD 1 illustrated in FIG. 1A and FIG. 1B is just an example, and the HMD is not limited to this. It is sufficient if the HMD 1 is worn on at least the user's head and includes a display panel that displays an image. The shapes and the like of the fitting band and the main body housing are not limited to those illustrated in FIG. 1A and FIG. 1B. In addition, FIG. 1B schematically illustrates the display unit 100 and the eyepiece 200, and the shapes and sizes thereof are not limited to those illustrated in FIG. 1B.

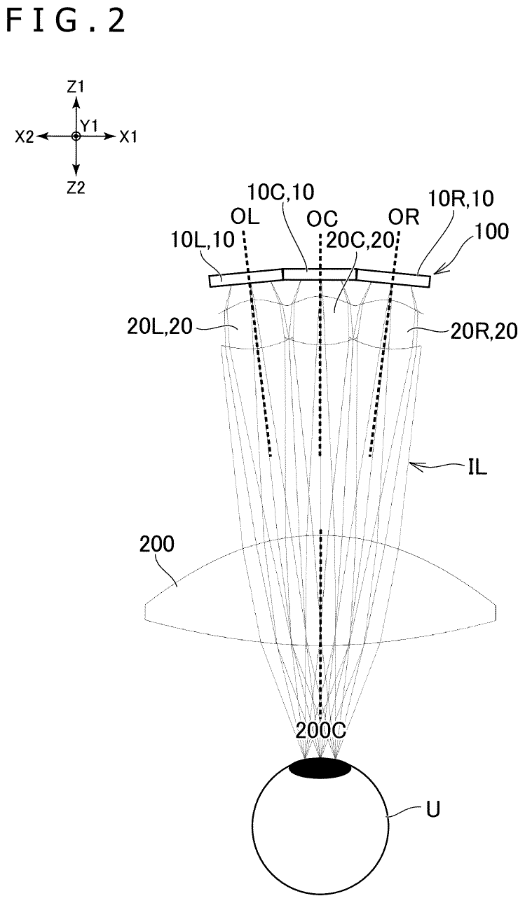

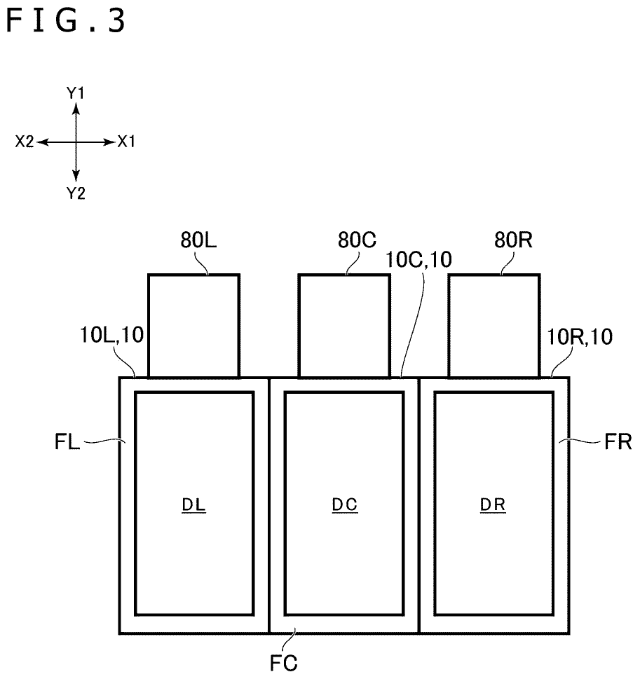

Next, details of configurations of the display panels and the optical system in the present embodiment will be described with reference to FIG. 2 and FIG. 3. FIG. 2 is a diagram schematically illustrating the configurations of the display panels and the optical system in the present embodiment. FIG. 3 is a plan view of the display panels in the present embodiment as viewed from the front. FIG. 2 illustrates the display panels and the optical system on either the right eye side or left eye side of a user U. The configuration illustrated in FIG. 2 is preferably provided on both the right eye side and the left eye side. However, the configuration is not limited to such a multiple-eye lens and may adopt a single-eye lens.

### Eyepiece 200

The eyepiece 200 constitutes part of the optical system of the HMD 1. The eyepiece 200 is a convex lens that is located in front of the right eye or left eye of the user U in the usage state and focuses image light IL emitted from the display panels 10 to the eyeball of the user U. The eyepiece 200 has a function of magnifying an image displayed on the display panels 10, to thereby allow the user to view the magnified image. Incidentally, the eyepiece 200 may include two or more lenses. In addition, the eyepiece 200 may be a Fresnel lens or a liquid crystal lens.

In FIG. 2, an optical axis 200C of the eyepiece 200 is indicated by a broken line. The optical axis is an imaginary axis that passes through the center of the eyepiece and is perpendicular to the surface of the eyepiece.

### Display Unit 100

The display unit 100 includes a plurality of display panels 10 and a plurality of lens parts 20 provided to correspond to the respective display panels 10. In the present embodiment, a description will be made of an example in which the plurality of display panels 10 include a front panel 10C, a right panel 10R, and a left panel 10L. Each of the front panel 10C, the right panel 10R, and the left panel 10L is preferably a micro-organic light-emitting diode (OLED) of 0.49 inches or less, for example. Arranging three micro-OLEDs of 0.49 inches (2 K) side by side can provide a micro-OLED equivalent to 1.5 inches (6 K) in appearance. The cost of using three micro-OLEDs of 0.49 inches is approximately one-tenth of the cost of using a micro-OLED of 1.5 inches.

In addition, in the present embodiment, a description will be made of an example in which the plurality of lens parts 20 include a front lens part 20C, a right lens part 20R, and a left lens part 20L. These lens parts 20 constitute the optical system together with the eyepiece 200. The lens parts 20 are arranged in front of the display panels 10 and are not in contact with the display panels 10. It is preferable to set the distances between the lens parts 20 and the display panels 10 appropriately so as to obtain a desired focal length. Incidentally, the distance between a central portion of the right lens part 20R and a central portion of the right panel 10R may be longer than the distance between a central portion of the front lens part 20C and a central portion of the front panel 10C. Similarly, the distance between a central portion of the left lens part 20L and a central portion of the left panel 10L may be longer than the distance between the central portion of the front lens part 20C and the central portion of the front panel 10C. This can reduce aberrations. Incidentally, the central portion of the right lens part 20R is a portion that faces the right panel 10R and through which an optical axis OR passes, and the central portion of the right panel 10R is a portion that faces the right lens part 20R and that is located in the center in the upward-downward direction and the left-right direction. Similarly, the central portion of the left lens part 20L is a portion that faces the left panel 10L and through which an optical axis OL passes, and the central portion of the left panel 10L is a portion that faces the left lens part 20L and that is located in the center in the upward-downward direction and the left-right direction.

It is to be noted that, in the present embodiment, in cases where the front panel 10C, the right panel 10R, and the left panel 10L do not need to be distinguished from one another in the description, they will be simply referred to as the “display panels 10.” Similarly, in cases where the front lens part 20C, the right lens part 20R, and the left lens part 20L do not need to be distinguished from one another in the description, they will be simply referred to as the “lens parts 20.”

### Display Unit 100: Display Panel 10

As illustrated in FIG. 3, the front panel 10C includes a display region DC and a frame region FC that surrounds the display region DC. The display region DC is a region that includes a plurality of unit pixels and displays an image. The frame region FC is a region that displays no image.

As illustrated in FIG. 2, the front panel 10C is disposed in front of the eyepiece 200. Specifically, the front panel 10C is disposed on an extension of the optical axis 200C of the eyepiece 200.

As illustrated in FIG. 3, the right panel 10R includes a display region DR and a frame region FR that surrounds the display region DR. The display region DR is a region that includes a plurality of pixels and displays an image. The frame region FR is a region that displays no image.

The right panel 10R is disposed adjacent to the front panel 10C on the right side of the front panel 10C. Thus, a left portion of the frame region FR of the right panel 10R and a right portion of the frame region FC of the front panel 10C are disposed adjacent to each other. The right panel 10R is not disposed on the extension of the optical axis 200C of the eyepiece 200. The right panel 10R is disposed on the right side of the optical axis 200C to face the eyepiece 200.

In addition, as illustrated in FIG. 2, the display surface of the display region DR is disposed to be inclined with respect to the display surface of the display region DC such that a right portion of the right panel 10R is located closer to the eyepiece 200. Specifically, the display surface of the display region DR of the right panel 10R is disposed to be inclined by 6.5 degrees with respect to the display surface of the display region DC of the front panel 10C. However, the arrangement is not limited to this. The display surface of the display region DR of the right panel 10R is preferably inclined by 6 to 7 degrees with respect to the display surface of the display region DC of the front panel 10C.

As illustrated in FIG. 3, the left panel 10L includes a display region DL and a frame region FL that surrounds the display region DL. The display region DL is a region that includes a plurality of pixels and displays an image. The frame region FL is a region that displays no image.

The left panel 10L is disposed adjacent to the front panel 10C on the left side of the front panel 10C. Thus, a right portion of the frame region FL of the left panel 10L and a left portion of the frame region FC of the front panel 10C are disposed adjacent to each other. The left panel 10L is not disposed on the extension of the optical axis 200C of the eyepiece 200. The left panel 10L is disposed on the left side of the optical axis 200C to face the eyepiece 200.

In addition, as illustrated in FIG. 2, the display surface of the display region DL is disposed to be inclined with respect to the display surface of the display region DC such that a left portion of the left panel 10L is located closer to the eyepiece 200. Specifically, the display surface of the display region DL of the left panel 10L is disposed to be inclined by 6.5 degrees with respect to the display surface of the display region DC of the front panel 10C. However, the arrangement is not limited to this. The display surface of the display region DL of the left panel 10L is preferably inclined by 6 to 7 degrees with respect to the display surface of the display region DC of the front panel 10C.

Incidentally, each display panel 10 may be a flexible panel having flexibility. For example, the left panel 10L and the right panel 10R may be flexible panels and be provided in a curved state.

### Display Unit 100: Lens Part 20

The front lens part 20C is disposed in front of the eyepiece 200. Specifically, the front lens part 20C is disposed on the extension of the optical axis 200C of the eyepiece 200. Thus, the front lens part 20C is disposed to face the front panel 10C.

The front lens part 20C is a convex lens that guides the image light IL emitted from the display region DC to the eyepiece 200 and magnifies the display region DC to thereby allow the user to view the magnified display region DC. The front lens part 20C is disposed such that an optical axis OC of the front lens part 20C is orthogonal to the display surface of the front panel 10C. The front lens part 20C preferably has substantially the same size as the front panel 10C or such a size as to cover at least half or more of the display surface of the front panel 10C.

The right lens part 20R is disposed adjacent to the front lens part 20C on the right side of the front lens part 20C. The right lens part 20R is disposed on the right side of the optical axis 200C to face the eyepiece 200. The right lens part 20R is not disposed on the extension of the optical axis 200C of the eyepiece 200.

The right lens part 20R is a convex lens that guides the image light IL emitted from the display region DR to the eyepiece 200 and magnifies the display region DR to thereby allow the user to view the magnified display region DR. The right lens part 20R is disposed such that the optical axis OR of the right lens part 20R is orthogonal to the display surface of the right panel 10R. The optical axis OR is thus inclined with respect to the optical axis OC. Specifically, the optical axis OR of the right lens part 20R is disposed to be inclined by 6.5 degrees with respect to the optical axis OC of the front lens part 20C. However, the arrangement is not limited to this. The optical axis OR of the right lens part 20R is preferably inclined by 6 to 7 degrees with respect to the optical axis OC of the front lens part 20C. The right lens part 20R preferably has substantially the same size as the right panel 10R or such a size as to cover at least half or more of the display surface of the right panel 10R.

The left lens part 20L is disposed adjacent to the front lens part 20C on the left side of the front lens part 20C. The left lens part 20L is disposed on the left side of the optical axis 200C to face the eyepiece 200. The left lens part 20L is not disposed on the extension of the optical axis 200C of the eyepiece 200.

The left lens part 20L is a convex lens that guides the image light IL emitted from the display region DL to the eyepiece 200 and magnifies the display region DL to thereby allow the user to view the magnified display region DL. The left lens part 20L is disposed such that the optical axis OL of the left lens part 20L is orthogonal to the display surface of the left panel 10L. The optical axis OL is thus inclined with respect to the optical axis OC. Specifically, the optical axis OL of the left lens part 20L is disposed to be inclined by 6.5 degrees with respect to the optical axis OC of the front lens part 20C. However, the arrangement is not limited to this. The optical axis OL of the left lens part 20L is preferably inclined by 6 to 7 degrees with respect to the optical axis OC of the front lens part 20C. The left lens part 20L preferably has substantially the same size as the left panel 10L or such a size as to cover at least half or more of the display surface of the left panel 10L.

In the present embodiment, the lens part 20 is illustrated as an aspheric lens. However, the lens part is not limited to this and may be a spherical lens or a freeform lens. In addition, in the present embodiment, illustrated is an example in which the front lens part 20C, the right lens part 20R, and the left lens part 20L are formed integrally with each other as illustrated in FIG. 2. However, they are not limited to this configuration and may be separate lenses. In a case where the front lens part 20C, the right lens part 20R, and the left lens part 20L are formed integrally with each other, the relative positional accuracy between the lens parts can be improved easily. In a case where the front lens part 20C, the right lens part 20R, and the left lens part 20L are formed as separate lenses, on the other hand, curved surfaces of the front lens part 20C, the right lens part 20R, and the left lens part 20L are formed in the same shape as illustrated in FIG. 2, which makes it possible to reduce the mold cost and avoid the complexity of process management. However, the front lens part 20C, the right lens part 20R, and the left lens part 20L may have different shapes from each other.

### Display Image

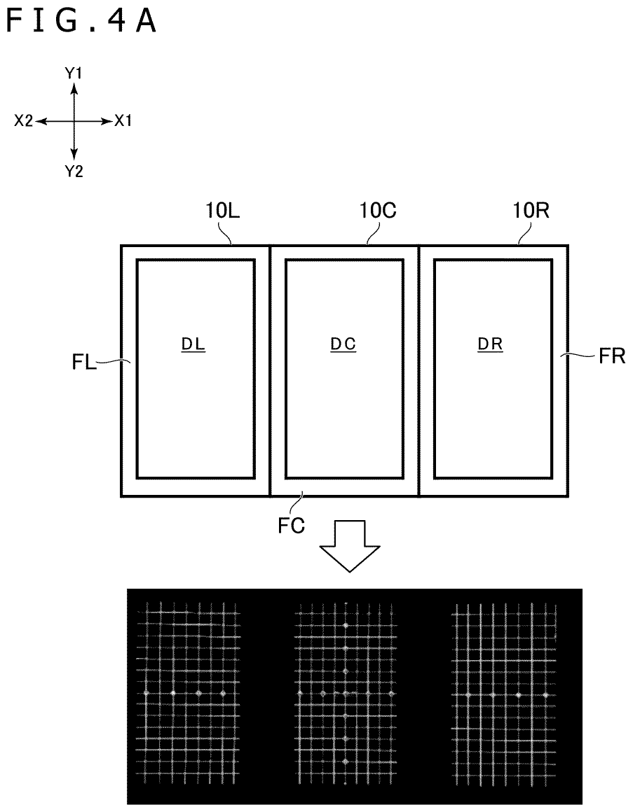

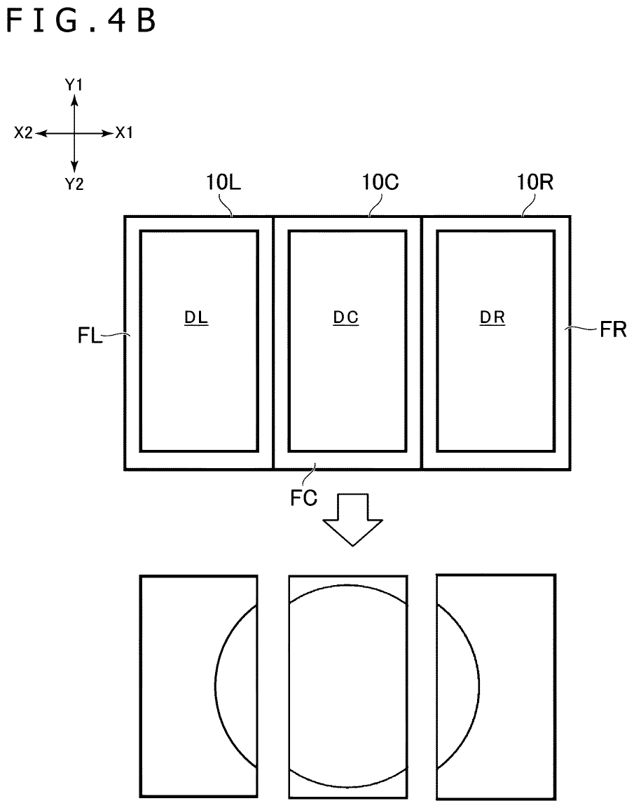

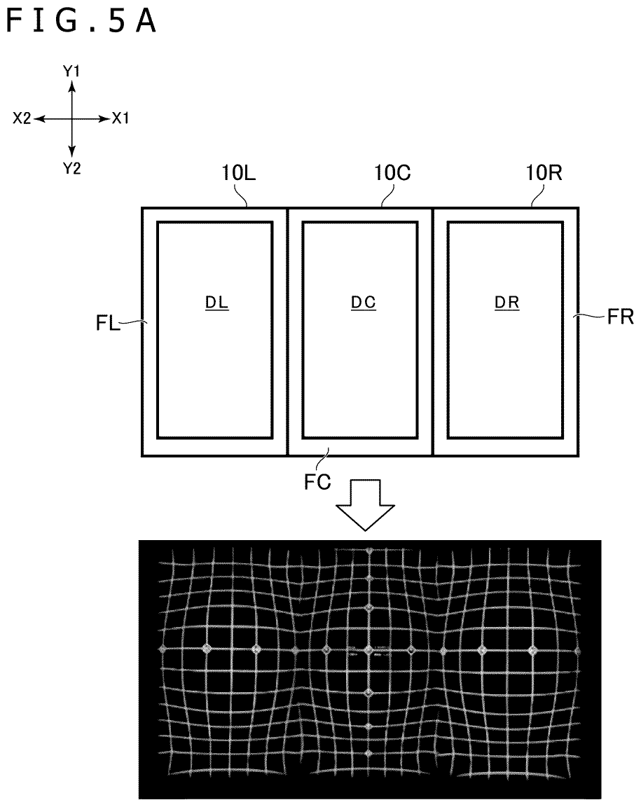

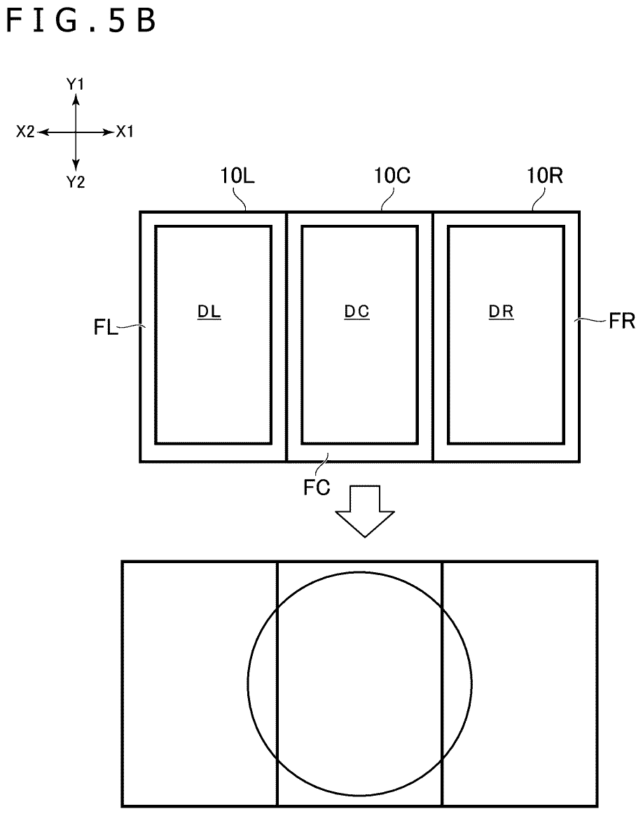

Next, display images to be displayed on the HMD 1 according to the present embodiment will be described mainly with reference to FIGS. 4A to 5B. FIG. 4A is a diagram illustrating an example of a display image in a case where a lattice pattern is displayed in each display region. FIG. 4B is a diagram illustrating an example of a display image in a case where a circular object is displayed. FIG. 5A is a diagram illustrating an example of a display image that the user can view via the lens parts in the case where the lattice pattern is displayed in each display region. FIG. 5B is a diagram illustrating an example of a display image that the user can view via the lens parts in the case where the circular object is displayed. Incidentally, an upper portion of each of FIGS. 4A to 5B illustrates a plan view (that is, the plan view illustrated in FIG. 3) of the display panels as viewed from the front, and a lower portion thereof illustrates a display image that the user can view.

The display region DC, the display region DR, and the display region DL together form one image. However, because each display panel 10 has the frame region as described with reference to FIG. 3, the one image is displayed as being separated at the frame regions as illustrated in the lower portions of FIG. 4A and FIG. 4B. That is, an image displayed in the display region DC and an image displayed in the display region DR are discontinuous with each other, and an image displayed in the display region DC and an image displayed in the display region DL are discontinuous with each other.

The lower portion of FIG. 4A illustrates a state in which the lattice pattern is displayed in each display region. As described above, due to the presence of the frame regions, the lattice patterns displayed in the respective display regions are viewed as being separated from one another.

The lower portion of FIG. 4B illustrates a state in which part of the circular object is displayed in each display region. As described above, due to the presence of the frame regions, the object is viewed as being discontinuous.

Accordingly, the present embodiment adopts the configuration including the lens parts 20 corresponding to the respective display panels 10. This allows the user U to view images displayed in the respective display regions, as one continuous image.

The lower portion of FIG. 5A illustrates a state in which the lattice patterns are viewed in such a manner that the distance between lattice points therein is greater than that in the lower portion of FIG. 4A. In addition, FIG. 5B illustrates a state in which the circular object is viewed as one continuous object. The object is viewed as one continuous object in this manner because the lens parts 20 are provided so as to magnify the images displayed in the respective display regions and cause the magnified images to be viewed.

Incidentally, because the user views the display regions via the lens parts 20, each display region is viewed in a distorted manner as illustrated in the lower portion of FIG. 5A. With regard to this, it is sufficient to make a distortion correction by using electronic means. That is, the amounts of distortion caused by the lenses are taken into consideration, and a distortion correction is made so as to display images having opposite distortion. As a result, the external shape of each display region is viewed as a rectangle as illustrated in the lower portion of FIG. 5B.

### Summary

The HMD 1 according to the present embodiment allows the user to view an image of high resolution with a wide angle of view by using inexpensive small-sized panels. In addition, it adopts the configuration in which the plurality of lens parts 20 are provided to correspond to the respective display panels 10, allowing the user to view one continuous image even with the display panels 10 having the frame regions.

Moreover, the use of a plurality of small-sized display panels can suppress the cost as compared with a case of using one large-sized display panel. In a case where a commercially available display panel whose display region has double the area is used, for example, a purchase cost may increase approximately 10 times or more.

In general, when an HMD needs to have a wide angle of view, increasing the resolution of an eyepiece requires an additional lens whose diameter and thickness are substantially the same as the eyepiece. The HMD is consequently increased in size in the forward-rearward direction. The present embodiment, however, adopts the configuration including, in addition to the eyepiece 200, the plurality of lens parts 20 arranged side by side in the left-right direction. This can shorten the focal length in the optical system without increasing the thickness of the eyepiece 200 or increasing the curvature of the surface of the eyepiece 200. It is therefore possible to provide the HMD 1 that achieves a higher resolution of a display image to be viewed, without an increase in size in the forward-rearward direction (depth direction). Incidentally, no other lens is preferably provided between the eyepiece 200 and the lens parts 20 in the forward-rearward direction.

Further, the image formation performance of the eyepiece 200 is higher on a side closer to the optical axis 200C, but is low on an outer edge side of the eyepiece 200. That is, on the outer edge side of the eyepiece 200, an image tends to be viewed in a blurred state as compared with that in the vicinity of the optical axis 200C. The present embodiment, however, adopts the configuration including the lens parts 20 provided in correspondence with the respective display regions, and can thereby improve visibility also in a region of the outer edge side of the eyepiece 200. In addition, as described above, in the present embodiment, the right panel 10R and the left panel 10L are arranged in a state of being inclined with respect to the front panel 10C such that they are located closer to the eyepiece 200, so that visibility can be improved also in the region of the outer edge side of the eyepiece 200.

### First Modification

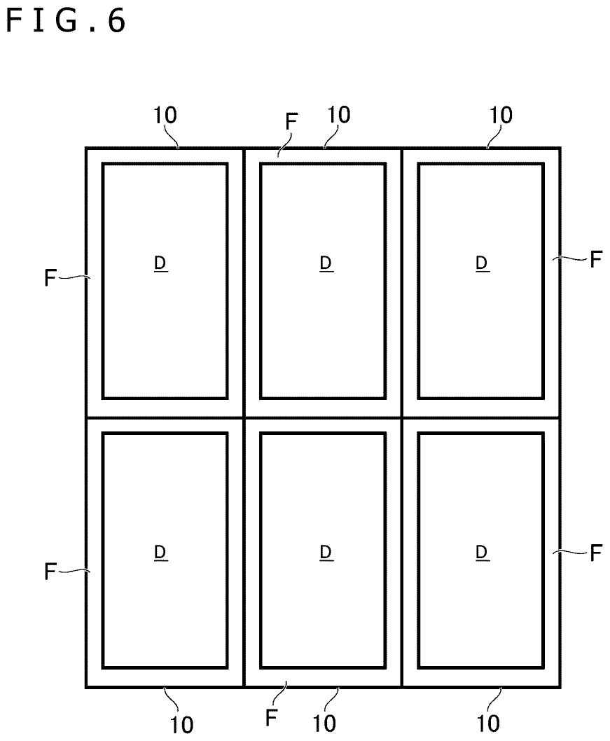

A first modification of the present embodiment will be described with reference to FIG. 6. FIG. 6 is a diagram illustrating display panels in the first modification.

In the present embodiment above, the description has been made of an example in which the display unit 100 has three display panels 10. However, the number of display panels 10 is not limited to this. For example, as illustrated in FIG. 6, the display unit 100 may have six display panels 10. In this case, as illustrated in FIG. 6, the display panels are preferably arranged adjacent to each other in the left-right direction and the upward-downward direction.

As illustrated in FIG. 6, when the number of display panels 10 arranged side by side in the left-right direction is an odd number, a display region D of the display panel 10 located in the center in the left-right direction can be disposed on the extension of the optical axis 200C of the eyepiece 200. However, the number of display panels 10 is not limited to this, and an even number of display panels 10 may be arranged side by side in the left-right direction. Incidentally, in this case, the display panels 10 are preferably arranged such that the frame regions F thereof are not disposed on the extension of the optical axis 200C of the eyepiece 200. This is because a region on and in the vicinity of the extension of the optical axis 200C is the most visible region to the user. If the frame region F is disposed on the extension of the optical axis 200C and connection portions between images to be viewed do not coincide with each other, the user may have a strong feeling of discomfort.

It is to be noted that the number of the display panels 10 and the number of the lens parts 20 are not limited to those in the examples of FIG. 2 and FIG. 6. It is preferable that at least a plurality of display regions D be provided and the number of lens parts 20 be the same as the display regions D.

### Second Modification

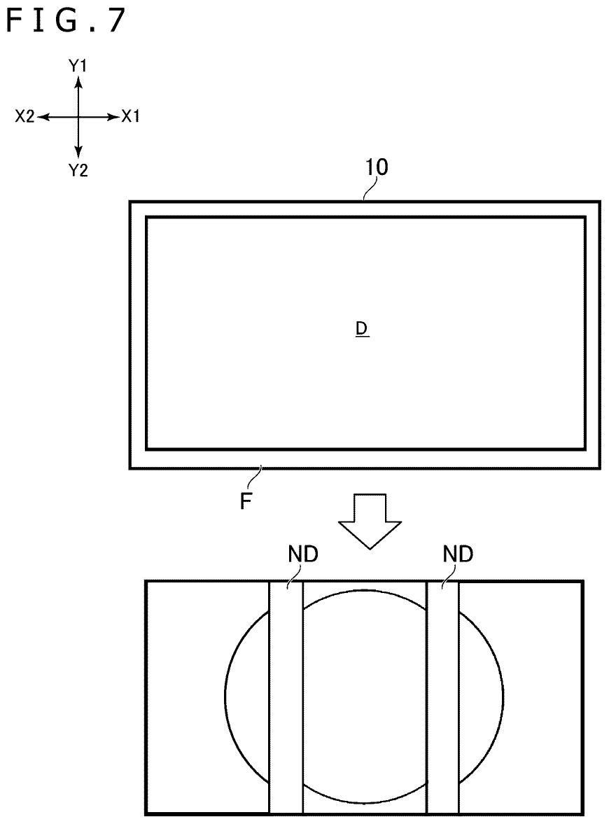

A second modification of the present embodiment will be described with reference to FIG. 7. FIG. 7 is a diagram illustrating a display panel in the second modification. Incidentally, an upper portion of FIG. 7 illustrates one display panel 10, and a lower portion of FIG. 7 illustrates a display region D to be viewed not via the lens parts 20.

In the present embodiment and the first modification above, the description has been made of an example in which the display unit 100 includes the plurality of display panels 10. Alternatively, the number of display panel 10 may be one.

Also in a case of using one display panel 10, the plurality of lens parts 20 are provided. Such a configuration can improve visibility on the outer edge side of the eyepiece 200. Here, in the configuration in which the plurality of lens parts 20 are disposed to face the one display panel 10 and arranged side by side in the left-right direction, when the lens parts 20 magnify the display region D and the display region D thus magnified is viewed, some portions of the display region D are viewed in an overlapping manner. Therefore, it is preferable in the second modification that the display region D include, in place of the frame regions F, regions in which no image is intentionally displayed. Specifically, as illustrated in FIG. 7, non-display regions ND are preferably provided. Accordingly, a plurality of display regions are formed in which a discontinuous image is displayed via the non-display regions ND. Alternatively, the same image may be displayed in portions of the display region D which are viewed in an overlapping manner via the lens parts 20.

### Specific Structure of Display Unit 100

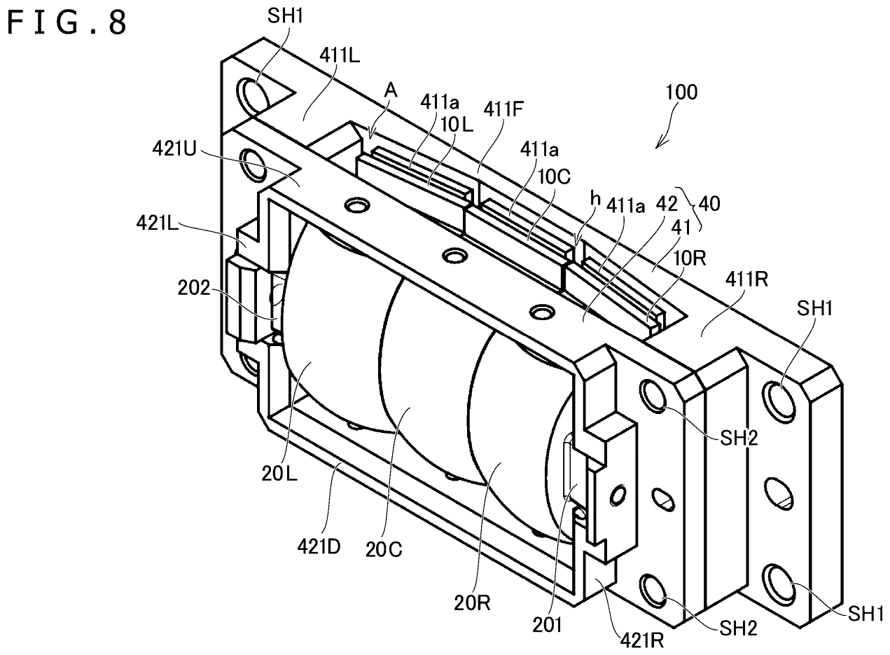

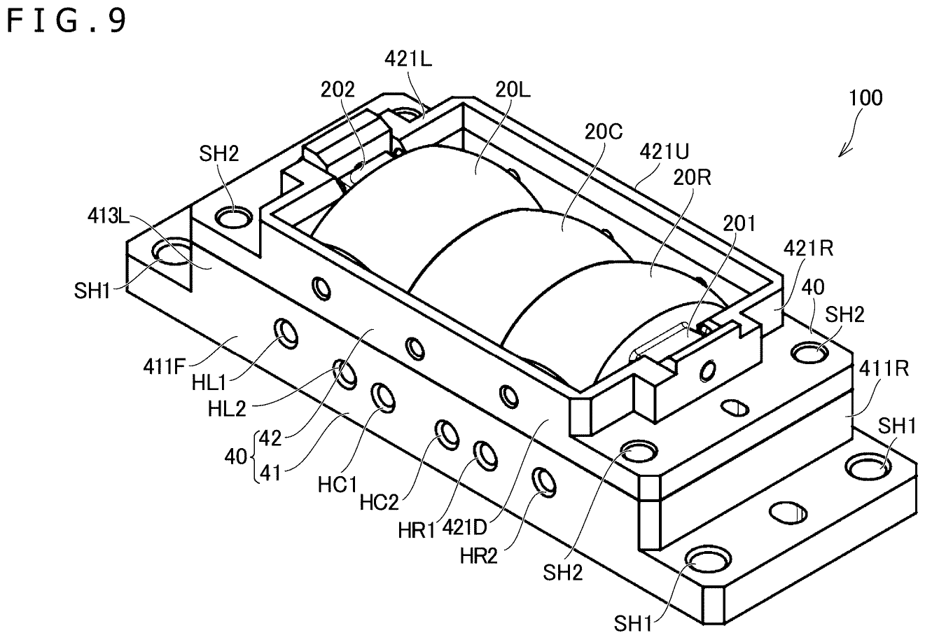

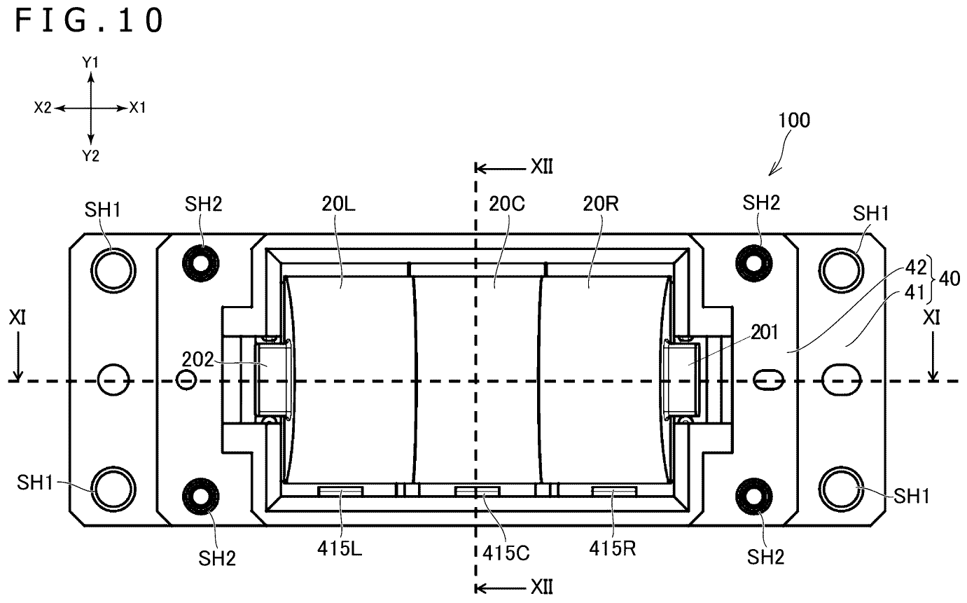

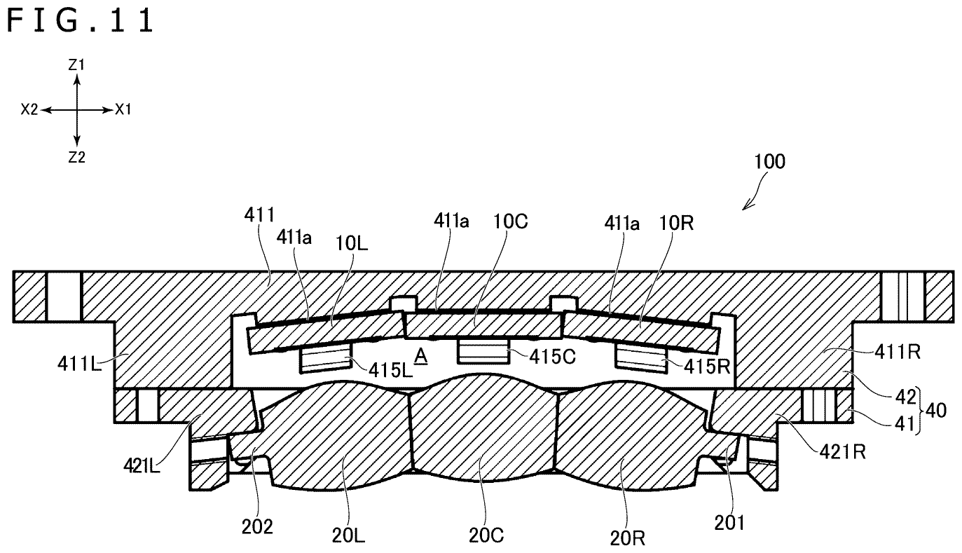

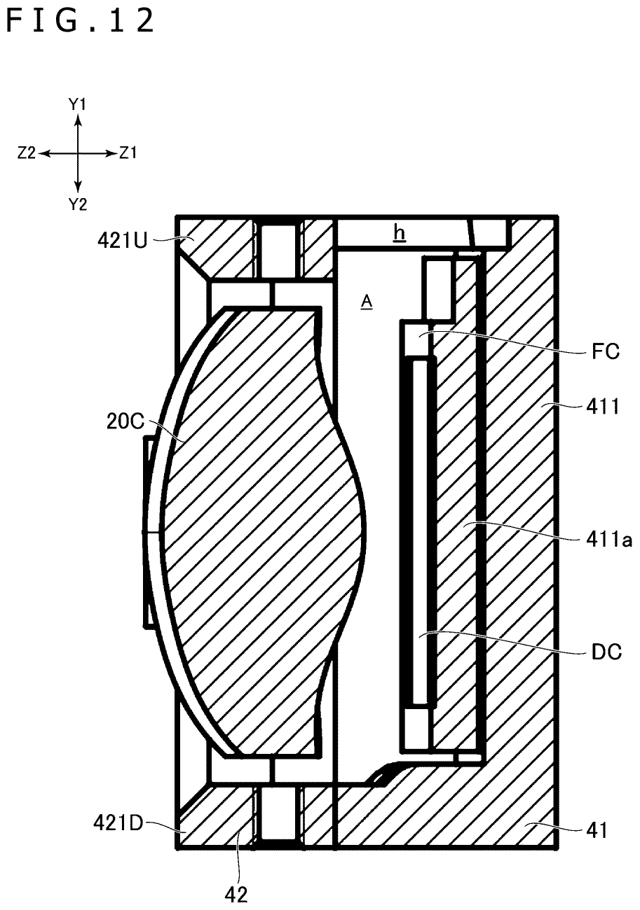

Next, a specific structure of the display unit 100 in the present embodiment will be described with reference to FIGS. 8 to 12. FIG. 8 is a perspective view of the display unit as viewed diagonally from the upper right. FIG. 9 is a perspective view of the display unit as viewed diagonally from the lower right. FIG. 10 is a front view of the display unit as viewed from the front. FIG. 11 is a sectional view illustrating a section of the display unit corresponding to a cutting line XI-XI of FIG. 10. FIG. 12 is a sectional view illustrating a section of the display unit corresponding to a cutting line XII-XII of FIG. 10.

The display unit 100 includes the display panels 10 and the lens parts 20, which have been described above, and a display panel holder 40 that holds the display panels 10 and the lens parts 20. The display panel holder 40 is a housing member that constitutes the external appearance of the display unit 100.

The display panel holder 40 includes a panel holding part 41 that internally houses and holds the display panels 10 and a lens holding part 42 that holds the lens parts 20 to expose the lens parts 20 from the display panel holder 40. It is sufficient if the panel holding part 41 and the lens holding part 42 have such a strength and rigidity as to be able to hold the display panels 10 and the lens parts 20. The panel holding part 41 and the lens holding part 42 may be made of resin or metal.

The panel holding part 41 includes a front wall portion 411F, a right wall portion 411R extending rearward from a right portion of the front wall portion 411F, and a left wall portion 411L extending rearward from a left portion of the front wall portion 411F. The front wall portion 411F, the right wall portion 411R, and the left wall portion 411L define a housing space A in which the display panels 10 are housed.

In addition, the front wall portion 411F includes holding bases 411a that hold the display panels 10 thereon. The holding bases 411a preferably hold the display panels 10 in such a manner as to allow adjustment of the positions and postures of the display panels 10. For example, the display panels 10 are preferably held on the holding bases 411a by such means as bonding or adhesion. As illustrated in FIG. 11, the respective holding bases 411a correspond to the front panel 10C, the right panel 10R, and the left panel 10L and are protruding in the forward direction from the front wall portion 411F. Protruding surfaces of the holding bases 411a are preferably flat.

In addition, the holding base 411a that holds the right panel 10R is preferably formed to be inclined with respect to the holding base 411a that holds the front panel 10C. The right panel 10R is thus held on the holding base 411a with the display surface of the display region DR inclined with respect to the display surface of the display region DC such that the right portion of the right panel 10R is located closer to the eyepiece 200.

Similarly, the holding base 411a that holds the left panel 10L is preferably formed to be inclined with respect to the holding base 411a that holds the front panel 10C. The left panel 10L is thus held on the holding base 411a with the display surface of the display region DL inclined with respect to the display surface of the display region DC such that the left portion of the left panel 10L is located closer to the eyepiece 200.

The panel holding part 41 is preferably fixed to the main body housing (not illustrated) of the HMD 1 by fixtures such as screws. In FIG. 8 and the like, illustrated is an example in which a plurality of screw holes SH1 are formed in right and left portions of the front wall portion 411F of the panel holding part 41 to fix the panel holding part 41 to the main body housing. The screw holes SH1 are holes that penetrate in the forward-rearward direction. Incidentally, not only the holes for inserting the fixtures therethrough but also holes or recesses for positioning may be formed in the panel holding part 41 as appropriate.

The lens holding part 42 includes an upper edge portion 421U, a lower edge portion 421D, a left edge portion 421L, and a right edge portion 421R. The upper edge portion 421U, the lower edge portion 421D, the left edge portion 421L, and the right edge portion 421R surround and hold the lens parts 20.

It is to be noted that, in the present embodiment, the front lens part 20C, the right lens part 20R, and the left lens part 20L are formed integrally with each other. That is, the front lens part 20C, the right lens part 20R, and the left lens part 20L are formed of one lens material with three curved surfaces formed thereon. In FIG. 10 and the like, illustrated is an example in which a right held portion 201 and a left held portion 202 are provided, the right held portion 201 protruding rightward from a right portion of the right lens part 20R, the left held portion 202 protruding leftward from a left portion of the left lens part 20L. When the right held portion 201 and the left held portion 202 are held by the lens holding part 42, positioning of the front lens part 20C, the right lens part 20R, and the left lens part 20L in the left-right direction, the upward-downward direction, and the forward-rearward direction is thereby performed.

The lens holding part 42 is preferably fixed to the panel holding part 41 by fixtures such as screws. In FIG. 8 and the like, illustrated is an example in which a plurality of screw holes SH2 are formed in the lens holding part 42 to fix the lens holding part 42 to the panel holding part 41. The screw holes SH2 are holes that penetrate in the forward-rearward direction. Incidentally, not only the holes for inserting the fixtures therethrough but also holes or recesses for positioning may be formed in the lens holding part 42 as appropriate.

### Positional Adjustment Of Display Panels 10

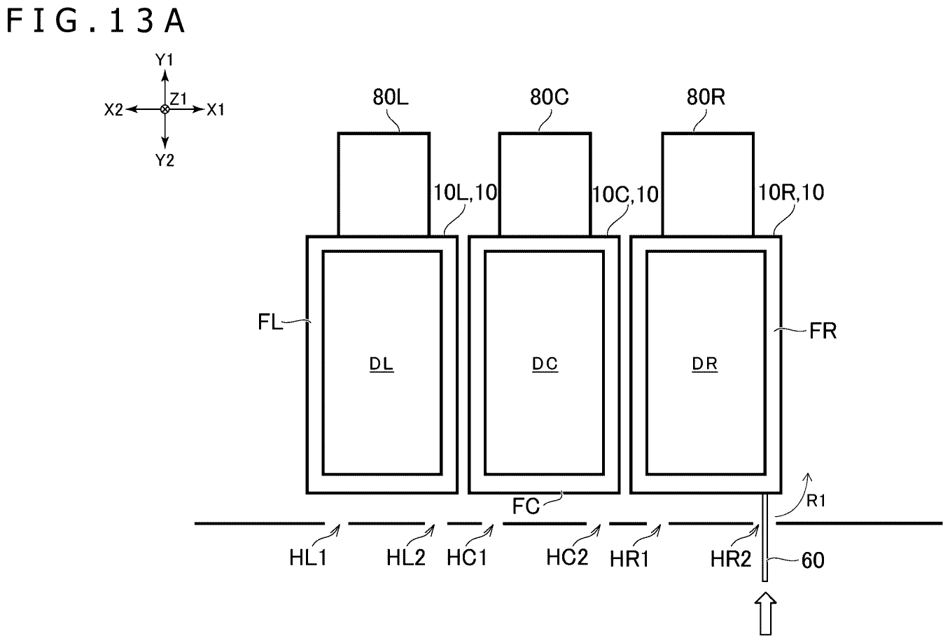

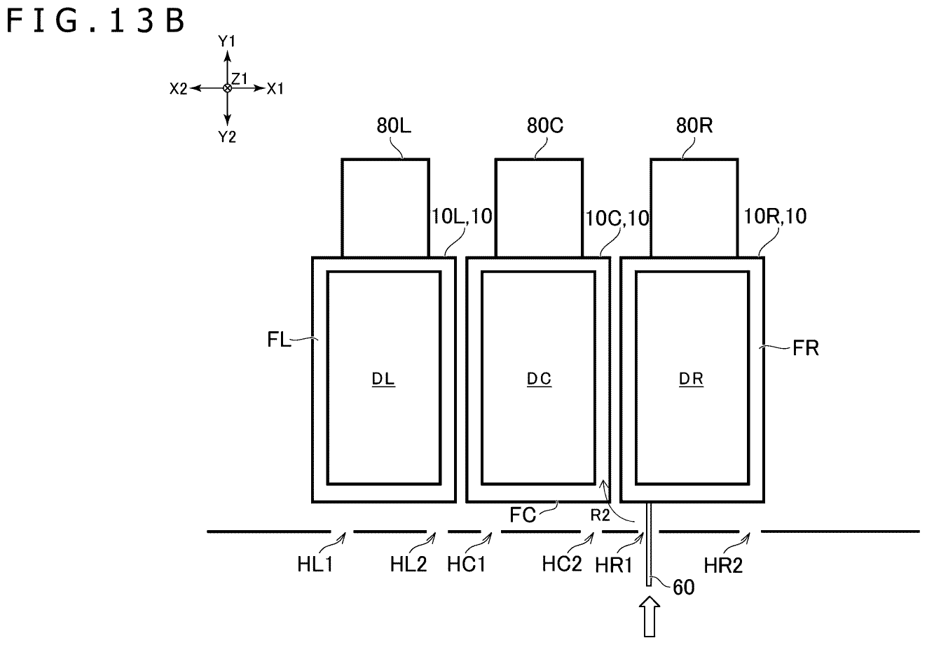

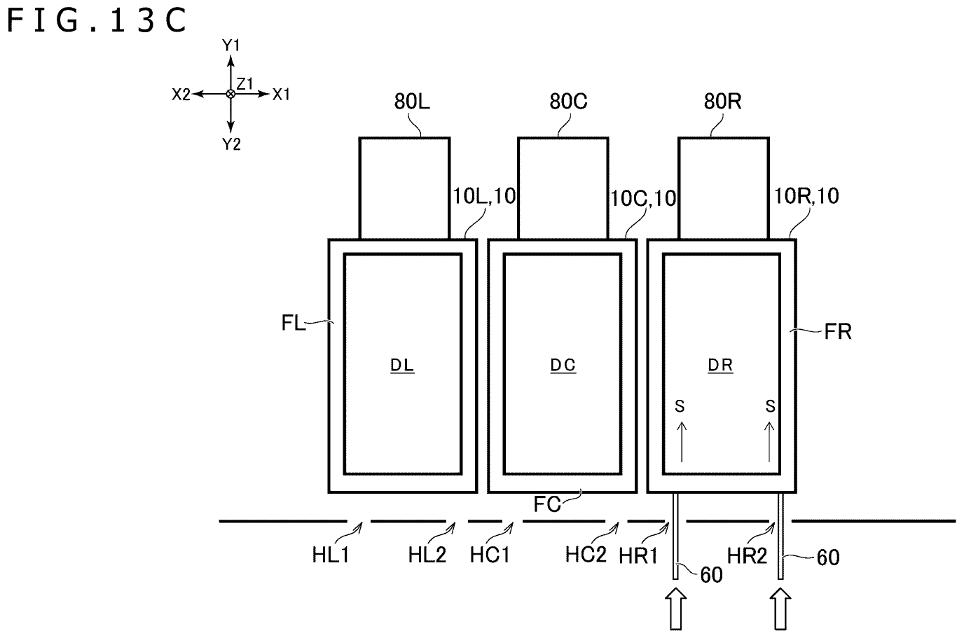

Next, the positional adjustment of the display panels 10 will be described mainly with reference to FIGS. 13A to 13C. FIGS. 13A to 13C are each a diagram schematically illustrating an example of a manner of making a positional adjustment of the display panel.

Positional accuracy of the display panels 10 is essential for the HMD 1. For example, in a case where a positional displacement occurs in a direction of rotation about an axis along a direction perpendicular to the display surface of the display panel 10, the user will view an inclined image. Particularly in the configuration using the plurality of display panels 10, a display screen is magnified by the lenses, and therefore, a high positional accuracy is required. As described with reference to FIGS. 5A and 5B and the like, a plurality of images are combined to form one image, and the image thus formed is viewed. Thus, in a case where a positional displacement occurs, for example, in a case where any of the display panels 10 is inclined improperly, a problem occurs at connection portions between the images. The user consequently has a feeling of discomfort.

Accordingly, the present embodiment adopts such a configuration that allows the positional adjustment of the display panels 10 after assembly of the display unit 100. Specifically, a configuration is adopted in which the panel holding part 41 of the display panel holder 40 has positional adjustment holes formed therein to receive an operation for the positional adjustment of the display panels 10 from the outside of the panel holding part 41.

More specifically, as illustrated in FIG. 9 and the like, positional adjustment holes HC1, HC2, HR1, HR2, HL1, and HL2 are formed in a lower portion of the panel holding part 41. The positional adjustment hole HC1 is formed to face the lower edge of a left portion of the front panel 10C housed in the panel holding part 41. The positional adjustment hole HC2 is formed to face the lower edge of a right portion of the front panel 10C housed in the panel holding part 41. The positional adjustment hole HR1 is formed to face the lower edge of a left portion of the right panel 10R housed in the panel holding part 41. The positional adjustment hole HR2 is formed to face the lower edge of the right portion of the right panel 10R housed in the panel holding part 41. The positional adjustment hole HL1 is formed to face the lower edge of the left portion of the left panel 10L housed in the panel holding part 41. The positional adjustment hole HL2 is formed to face the lower edge of a right portion of the left panel 10L housed in the panel holding part 41.

Here, a description will be made of a case of making a positional adjustment of the right panel 10R. FIG. 13A illustrates a state in which the lower edge of the right portion of the right panel 10R is pressed by a positional adjustment pin 60 being inserted through the positional adjustment hole HR2. Such an operation rotationally moves the right panel 10R in a direction of inclining the display surface of the right panel 10R (counterclockwise direction R1 in FIG. 13A) with respect to the upward-downward direction and the left-right direction. On the other hand, FIG. 13B illustrates a state in which the lower edge of the left portion of the right panel 10R is pressed by the positional adjustment pin 60 being inserted through the positional adjustment hole HR1. Such an operation rotationally moves the right panel 10R in a direction of inclining the display surface of the right panel 10R (clockwise direction R2) with respect to the upward-downward direction and the left-right direction.

Pressing the right panel 10R from the outside by using the positional adjustment pin 60 in this manner can finely adjust the inclination of the right panel 10R.

In addition, as illustrated in FIG. 13C, when the positional adjustment pins 60 are inserted through both the positional adjustment hole HR1 and the positional adjustment hole HR2 at the same time, the lower edges of the right portion and left portion of the right panel 10R can thereby be pressed. The right panel 10R is thereby translated in the upward direction (S1 direction). Thus, the present embodiment allows the positional adjustment of the right panel 10R not only in inclination directions but also in a parallel direction.

Incidentally, while the description has been made by taking, as an example, the positional adjustment of the right panel 10R in FIGS. 13A to 13C, the positional adjustment can also be made to the front panel 10C and the left panel 10L by a similar method.

Incidentally, as illustrated in FIG. 13A and the like, the display panels 10 are preferably arranged adjacent to each other with a space left therebetween such that the display surfaces are displaceable in an inclining direction with respect to the upward-downward direction and the left-right direction. This enables the positional adjustment to be made individually to each of the display panels 10. However, the configuration is not limited to this, and the plurality of display panels 10 may be formed integrally with each other and adjusted in position integrally.

In addition, the panel holding part 41 may be provided with protrusions for positioning the display panels 10 in the upward-downward direction before the above-described positional adjustment is made. In FIG. 10 and FIG. 11, illustrated is a protrusion 415C that protrudes upward and abuts against the lower edge of the front panel 10C in order to position the front panel 10C in the upward-downward direction. Similarly, there are also illustrated protrusions 415R and 415L that protrude upward in order to position the right panel 10R and the left panel 10L, respectively, in the upward-downward direction. Incidentally, these protrusions are not essential.

In addition, although a detailed description is omitted, the lens parts 20 held by the lens holding part 42 may also be adjustable in position by a method similar to that for the display panels 10. That is, the lens holding part 42 may also have lens positional adjustment holes formed therein to receive an operation for the positional adjustment of the lens parts 20 from the outside of the lens holding part 42

In the present embodiment, as described above, the display panels 10 and the lens parts 20 are not in contact with each other, and therefore, the display panels 10 and the lens parts 20 can be adjusted in position independently of each other.

The use of the display panel holder 40 described above allows the positions of the display panels 10 to be finely adjusted after the display panels 10 are housed within the holder. In addition, making a positional adjustment using means that comes into physical contact with the display panels 10 enables a fine positional adjustment according to individual differences. Moreover, when the positional adjustment is made by using the means that comes into physical contact with the edges of the display panels 10, the display regions of the display panels are not damaged.

Incidentally, it is sufficient to, after the positional adjustment using the physical means described in the present embodiment, further perform a positional adjustment using electronic means related to display. The positional adjustment using the electronic means is easily made in parallel directions (the upward-downward direction and the left-right direction) but has difficulty in achieving accuracy in inclination directions. The positional adjustment using the physical means is therefore useful.

### Another Example of Positional Adjustment of Display Panels 10

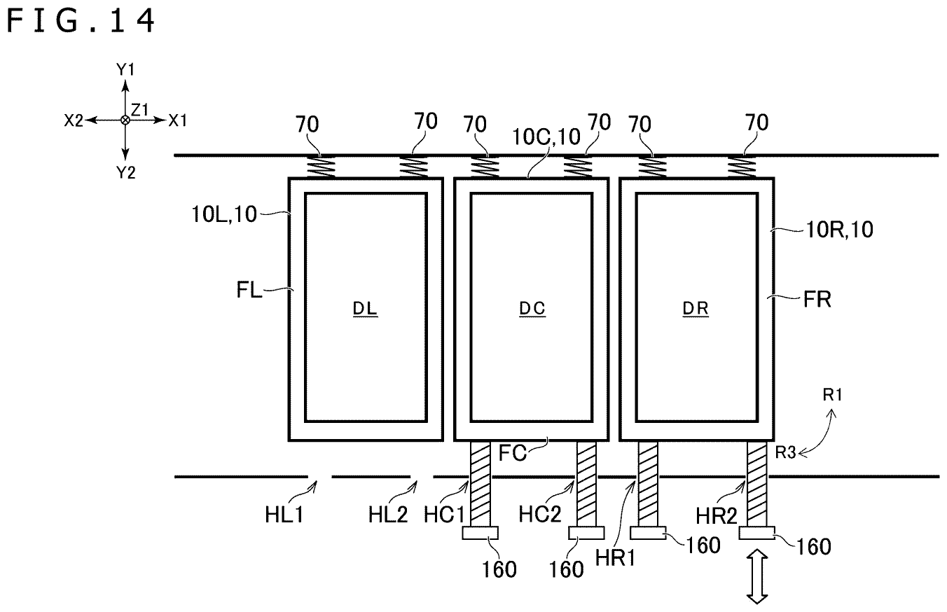

Another example of the positional adjustment of the display panels 10 will further be described with reference to FIG. 14. FIG. 14 is a diagram schematically illustrating an example of a manner of making a positional adjustment of a display panel.

In the example illustrated in FIG. 14, internal threads are formed on inner circumferential surfaces of the positional adjustment holes, which are formed to receive an operation for the positional adjustment of the display panels 10 from the outside of the panel holding part 41. In this case, as illustrated in FIG. 14, screws 160 having external threads formed on outer circumferential surfaces thereof, the external threads meshing with the internal threads, are preferably used in place of the positional adjustment pins 60. In addition, elastic springs 70 are preferably provided between the upper edges of the display panels 10 and portions of the panel holding part 41.

FIG. 14 illustrates a state in which the screw 160 inserted in the positional adjustment hole HR2 is moved in a direction of pushing the lower edge of the right portion of the right panel 10R or is moved in a direction of being removed from the positional adjustment hole HR2.

In this manner, the inclination of the right panel 10R can be adjusted. That is, as in the example described with reference to FIG. 13A, the right panel 10R can rotationally be moved in a direction of inclining the display surface of the right panel 10R (counterclockwise direction R1 in FIG. 14) with respect to the upward-downward direction and the left-right direction. Further, in the example of FIG. 14, as the screw 160 is moved in the direction of being removed from the positional adjustment hole HR2, the elastic spring 70 elastically presses the upper edge of the right portion of the right panel 10R. The right panel 10R is thereby rotationally moved in a direction of inclining the display surface of the right panel 10R (clockwise direction R3 in FIG. 14) with respect to the upward-downward direction and the left-right direction. Thus, in the example illustrated in FIG. 14, in a case where the right panel 10R is moved too much in the R1 direction, it is possible to make a positional adjustment in a direction of returning from a position to which the right panel 10R is moved too much.

Incidentally, FIG. 14 does not illustrate screws for making a positional adjustment of the left panel 10L. In addition, FIG. 14 illustrates an example in which two elastic springs 70 are disposed to be elastically in contact with the upper edge of each display panel 10. However, the number and arrangement of elastic springs 70 are not limited to this. In addition, the configuration is not limited to the springs, and elastic members that produce an elastic force acting in a direction opposite to the insertion direction of the screws 160 or the like are preferably provided.

### Flexible Wiring Board

As illustrated in FIGS. 3 and 13A and the like, the display panels 10 are preferably provided with flexible wiring boards 80C, 80R, and 80L for supplying image signals to the respective display regions of the display panels 10. Incidentally, the flexible wiring boards 80C, 80R, and 80L may be wiring boards that supply power.

The flexible wiring boards 80C, 80R, and 80L are preferably disposed to extend in a direction orthogonal to the direction in which the display panels 10 are arranged (left-right direction in the present embodiment). FIGS. 3 and 13A and the like illustrate a state in which the flexible wiring boards are attached to upper portions of the respective display panels 10 and are disposed to extend upward. In addition, as illustrated in FIG. 8 and the like, an opening h that exposes the upper portions of the display panels 10 is preferably formed in an upper portion of the display panel holder 40. As illustrated in FIG. 8, the opening h is defined by the front wall portion 411F, the right wall portion 411R, the left wall portion 411L, and the upper edge portion 421U.

With the above configuration, the flexible wiring board can be connected to each of the plurality of display panels 10 housed in the display panel holder 40, from the outside of the display panel holder 40. Incidentally, figures other than FIG. 3 and FIGS. 13A to 13C do not illustrate the flexible wiring boards.

### SUPPLEMENTARY NOTE

For example, the display panel holder and the HMD can also take the following configurations.
(1) A display panel holder for holding a display panel provided in a head-mounted display that is worn on a head of a user, the display panel holder including:
   a panel holding part that internally houses and holds one or more display panels each having a display region for displaying an image,
   the panel holding part having positional adjustment holes formed therein to receive an operation for a positional adjustment of the display panel from an outside of the panel holding part.
(2) The display panel holder according to (1), in which
   the positional adjustment holes are formed to face at least a lower edge of a right portion and a lower edge of a left portion, respectively, of the display panel housed in the panel holding part.
(3) The display panel holder according to (1) or (2), in which
   the one or more display panels include at least a first display panel and a second display panel separate from the first display panel, and
   the panel holding part has a first positional adjustment hole and a second positional adjustment hole formed therein, the first positional adjustment hole being used to receive an operation for a positional adjustment of the first display panel from the outside of the panel holding part, the second positional adjustment hole being used to receive an operation for a positional adjustment of the second display panel from the outside of the panel holding part.
(4) The display panel holder according to (3), in which
   the first display panel and the second display panel are arranged adjacent to each other with a space left therebetween such that display surfaces of the first display panel and the second display panel are displaceable in an inclining direction with respect to an upward-downward direction and a left-right direction.
(5) The display panel holder according to (3) or (4), in which
   the one or more display panels further include a third display panel,
   the panel holding part includes a first holding base that holds the first display panel, a second holding base that holds the second display panel, and a third holding base that holds the third display panel,
   the second holding base is disposed adjacent to the first holding base on a left side of the first holding base and is inclined with respect to the first holding base, and
   the third holding base is disposed adjacent to the first holding base on a right side of the first holding base and is inclined with respect to the first holding base.
(6) The display panel holder according to any one of (1) to (5), in which
   an internal thread is formed on an inner circumferential surface of each of the positional adjustment holes.
(7) The display panel holder according to (6), in which
   the panel holding part is provided with an elastic member that produces an elastic force acting on the panel in a direction opposite to an insertion direction of a fixture having an outer circumferential surface formed thereon an external thread that meshes with the internal thread.
(8) The display panel holder according to any one of (1) to (7), including:
   a lens holding part that holds a lens part in such a manner as to expose the lens part from the display panel holder, the lens part being configured to magnify the image to thereby allow the user to view the magnified image.
(9) The display panel holder according to (8), in which
   the lens holding part has a lens positional adjustment hole formed therein to receive an operation for a positional adjustment of the lens part from an outside of the lens holding part.
(10) A head-mounted display that is worn on a head of a user, the head-mounted display including:
   an eyepiece located in front of an eye of the user wearing the head-mounted display; one or more display panels each having a display region for displaying an image;
   a lens part configured to guide image light emitted from the display region to the eyepiece and magnify the image to thereby allow the user to view the magnified image; and
   a display panel holder that holds the lens part and internally houses and holds the one or more display panels,
   the display panel holder having positional adjustment holes formed therein to receive an operation for a positional adjustment of the display panel from an outside of the display panel holder.

### REFERENCE SIGNS LIST

1: HMD
10: Display panel
20: Lens part
40: Display panel holder
200: Eyepiece

1-10. (canceled)

11. A display panel holder for use in a head-mounted display that is worn on a head of a user, the display panel holder comprising:
a panel holding part configured for internally supporting one or more display panels therewith, each one of the one or more display panels comprising a display region for displaying an image therewith,
wherein the panel holding part comprises one or more positional adjustment holes formed therein, each of the one or more positional adjustment holes being configured to receive an operation for performing a positional adjustment of the one or more display panels from outside the panel holding part.

12. The display panel holder of claim 11, wherein
the one or more positional adjustment holes are disposed at at least one of a lower edge of a right portion and a lower edge of a left portion of one of the one or more display panels supported in the panel holding part.

13. The display panel holder of claim 11, wherein
the one or more display panels comprises at least a first display panel and a second display panel, the second display panel being spaced apart from the first display panel,
wherein the panel holding part comprises:
a first positional adjustment hole configured to receive the operation for positional adjustment of the first display panel from the outside of the panel holding part, and
a second positional adjustment hole configured to receive the operation for positional adjustment of the second display panel from the outside of the panel holding part, and
wherein the positional adjustment of the first display panel being independently operable from the positional adjustment of the second display panel.

14. The display panel holder of claim 13, wherein
the first display panel and the second display panel are disposed adjacent to and spaced apart from each other such that a display surface of each one of the first display panel and the second display panel is displaceable in an inclining direction with respect to an upward-downward direction and a left-right direction.

15. The display panel holder of claim 13, wherein
the one or more display panels further comprises a third display panel, the third display panel being spaced apart from the first display panel and the second display panel,
the panel holding part further comprises a first holding base configured for supporting the first display panel, a second holding base configured for supporting the second display panel, and a third holding base configured for supporting the third display panel,
the second holding base is disposed adjacent to and at an incline with respect to the first holding base on a left side of the first holding base, and
the third holding base is disposed adjacent to and at an incline with respect to the first holding base on a right side of the first holding base.

16. The display panel holder of claim 11, wherein each of the one or more positional adjustment holes comprises an internal thread formed from an inner circumferential surface of the each of the one or more positional adjustment holes.

17. The display panel holder of claim 16, wherein
the panel holding part further comprises an elastic member configured for producing an elastic force to act on the one or more display panels.

18. The display holder of claim 16, wherein the elastic member is further configured for producing the elastic force in a direction opposite to an insertion direction of a fixture having an external thread formed on an outer circumferential surface thereof, the external thread being configured to mesh with the internal thread.

19. The display panel holder of claim 11, further comprising:
a lens holding part configured for supporting a lens part while exposing the lens part from the display panel holder, the lens part being configured to magnify the image for viewing by the user.

20. The display panel holder of claim 19, wherein
the lens holding part comprises a lens positional adjustment hole formed therein to receive an operation for a positional adjustment of the lens part from an outside of the lens holding part.

21. A head-mounted display that is worn on a head of a user, the head-mounted display comprising:
an eyepiece located in front of an eye of the user wearing the head-mounted display;
one or more display panels, each of the one or more display panels comprising a display region for displaying an image therewith;
a lens part configured to guide image light emitted from the display region to the eyepiece and magnify the image for viewing by the user; and
a display panel holder configured for holding the lens part and the one or more display panels,
wherein the display panel holder comprises one or more positional adjustment holes formed therein, each of the one or more positional adjustment holes being configured to receive an operation for a positional adjustment of the one or more display panels from outside the display panel holder.

22. The head-mounted display of claim 21, wherein the one or more of the positional adjustment holes are disposed at at least one of a lower edge of a right portion and a lower edge of a left portion of one of the one or more display panels supported in the panel holding part.

23. The head-mounted display of claim 21, wherein
the one or more display panels comprises at least a first display panel and a second display panel, the second display panel being spaced apart from the first display panel,
wherein the panel holding part comprises:
a first positional adjustment hole configured to receive the operation for positional adjustment of the first display panel from the outside of the panel holding part, and
a second positional adjustment hole configured to receive the operation for positional adjustment of the second display panel from the outside of the panel holding part, and
wherein the positional adjustment of the first display panel being independently operable from the positional adjustment of the second display panel.

24. The head-mounted display of claim 23, wherein
the first display panel and the second display panel are disposed adjacent to and spaced apart from each other such that a display surface of each one of the first display panel and the second display panel is displaceable in an inclining direction with respect to an upward-downward direction and a left-right direction.

25. The head-mounted display of claim 23, wherein
the one or more display panels further comprises a third display panel, the third display panel being spaced apart from the first display panel and the second display panel,
the panel holding part further comprises a first holding base configured for supporting the first display panel, a second holding base configured for supporting the second display panel, and a third holding base configured for supporting the third display panel,
the second holding base is disposed adjacent to and at an incline with respect to the first holding base on a left side of the first holding base, and
the third holding base is disposed adjacent to and at an incline with respect to the first holding base on a right side of the first holding base.

26. The head-mounted display of claim 21, wherein each of the one or more positional adjustment holes comprises an internal thread formed from an inner circumferential surface of the each of the one or more positional adjustment holes.

27. The head-mounted display of claim 26, wherein
the panel holding part further comprises an elastic member configured for producing an elastic force to act on the one or more display panels.

28. The head-mounted display of claim 26, wherein the elastic member is further configured for producing the elastic force in a direction opposite to an insertion direction of a fixture having an external thread formed on an outer circumferential surface thereof, the external thread being configured to mesh with the internal thread.

29. The head-mounted display of claim 21, further comprising:
a lens holding part configured for supporting a lens part while exposing the lens part from the display panel holder, the lens part being configured to magnify the image for viewing by the user.

30. The head-mounted display of claim 29, wherein
the lens holding part comprises a lens positional adjustment hole formed therein to receive an operation for a positional adjustment of the lens part from an outside of the lens holding part.
